(19) United States
(12) Patent Application Publication
(10) Pub. No.: US 2012/0072792 A1
(43) Pub. Date: Mar. 22, 2012

(54) MEMORY TESTER AND COMPILER WHICH MATCHES A TEST PROGRAM

(75) Inventor: Yoshihiro SAKAMOTO, Kanagawa-ken (JP)

(73) Assignee: Kabushiki Kaisha Toshiba, Tokyo (JP)

(21) Appl. No.: 13/050,366

(22) Filed: Mar. 17, 2011

(30) Foreign Application Priority Data
Sep. 17, 2010 (JP) 2010-209199

(51) Int. Cl. G11C 29/08; G06F 11/263; G11C 29/18

(52) U.S. Cl. 714/718; 365/201; 714/E11.177

(57) ABSTRACT

According to one embodiment, a memory tester is provided. The memory tester has first and second operation registers, a first selector, and first and second burst address generating circuits. The first operation register stores a first operation variable. The second operation register stores a second operation variable. The first selector outputs the first and second operation variables stored in the first and second operation registers selectively, as a burst address operation variable, based on a selection signal. The first and second burst address generating circuits are capable of generating first and second burst address signals based on the first and second operation variables outputted from the first selector, respectively.

CROSS-REFERENCE TO RELATED APPLICATION(S)

This application is based upon and claims the benefit of priority from the prior Japanese Patent Application No. 2010-209199, filed on Sep. 17, 2010, the entire contents of which are incorporated herein by reference.

### FIELD

Embodiments described herein relate generally to a memory tester and a compiler which matches a test program.

### BACKGROUND

A synchronous memory device such as a SDRAM is known as a memory device. The synchronous memory device operates in synchronization with a high-speed clock signal. In the synchronous memory device, read or write operation is performed according to a burst system in order to speed up consecutive accesses.

In the burst system, data existing on the same row address is consecutively read or written, as a block unit of data corresponding to two, four or eight words. Further, in the burst system, a start address, i.e. a burst address, is provided as an address for accessing the memory. Subsequent addresses for accessing the memory are automatically generated inside the synchronous memory device. As a system for generating the addresses automatically, two kinds of types that are a linear type and an interleave type.

A memory tester which tests a memory device in the burst system is provided with burst address generating circuits for linear and interleave uses, in order to generate burst addresses corresponding to the two types.

In the respective burst address generating circuits, a predetermined logical operation is performed between a lap address value outputted from a pattern generator and an operation variable value stored in a burst address control register which is controlled by a test program, so that a burst address is generated. Thus, two test programs are necessary separately for the linear and interleave uses in order to control the burst address control register.

### BRIEF DESCRIPTION OF THE DRAWINGS

FIG. 1 is a block diagram showing a memory tester according to an embodiment;

FIG. 2 is a circuit diagram showing an example of a linear burst address generating circuit;

FIG. 3 is a circuit diagram showing an example of an interleave burst address generating circuit;

FIG. 4 shows a description example of a test program which is executed in the memory tester according to the embodiment;

FIGS. 5A and 5B are diagrams showing example values generated by the test program shown in FIG. 4;

FIGS. 6A and 6B are diagrams showing example values generated by the test program shown in FIG. 4;

FIG. 7 is a diagram schematically showing a processing flow of a compiler for compiling the test program shown in FIG. 4;

FIG. 8 is a block diagram showing an example of a memory tester for executing an object file obtained from the compiler of FIG. 7;

FIG. 9 is a circuit diagram showing an example of an L/I selector;

FIG. 10 is a circuit diagram showing an example of a selector;

FIG. 11 is a flow chart to generate a burst address using the memory tester according to the embodiment; and

FIG. 12 is a flow chart to produce object files for generating two kinds of burst addresses.

### DETAILED DESCRIPTION

According to one embodiment, a memory tester is provided. The memory tester has first and second operation registers, a first selector, and first and second burst address generating circuits. The first operation register stores a first operation variable. The second operation register stores a second operation variable. The first selector outputs the first and second operation variables stored in the first and second operation registers selectively, as a burst address operation variable, based on a selection signal. The first and second burst address generating circuits are capable of generating first and second burst address signals based on the first and second operation variables outputted from the first selector, respectively.

According to another embodiment, a compiler which is capable of being executed by a computer is provided. The compiler includes converting first and second operation variables described in one unit of test program into first and second burst address operation variables, respectively. The compiler includes generating a first source code including the first burst address operation variable and generating a second source code including the second burst address operation variable, the first source code being separated from the second source code. Further, the compiler includes compiling the first and second source codes and generating first and second object files, respectively.

Hereinafter, further embodiments will be described with reference to the drawings. In the drawings, the same reference numerals denote the same or similar portions respectively.

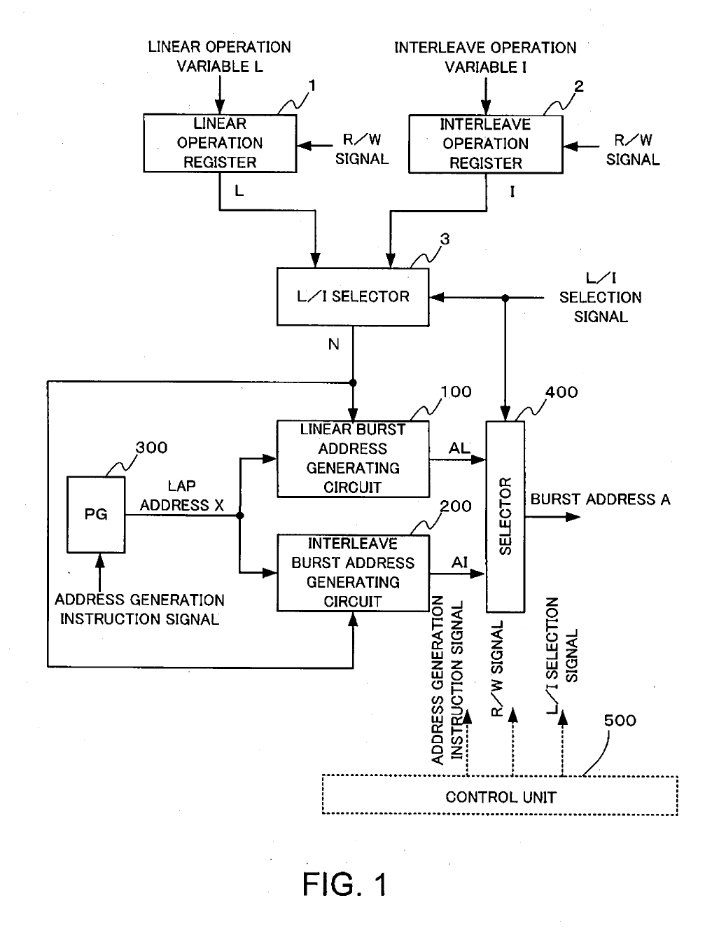

A first embodiment will be described with reference to FIG. 1. FIG. 1 is a block diagram showing a memory tester according to an embodiment.

As shown in FIG. 1, a memory tester according to the embodiment is provided with a linear burst address generating circuit 100, an interleave burst address generating circuit 200, a linear operation register 1, an interleave operation register 2, a L/I selector 3, a pattern generator (PG) 300, a selector 400 and a control unit 500. The control unit 500 controls the memory tester in whole to test a memory device to be tested. The terms “linear” and “interleave” indicate types of memories to be tested by a memory tester, respectively.

The linear operation register 1 store a linear operation variable L and the interleave operation register 2 store an interleave operation variable I separately. The linear and the interleave operation variables L, I are obtained by execution of different arithmetic expressions described in the same test program, which is installed in the control unit 500. R/W signal is inputted into the linear operation register 1 and the interleave operation register 2. The linear operation register 1 and the interleave operation register 2 is controlled by R/W signal.

The L/I selector 3 selects one of an output of the linear operation register 1 and an output of the interleave operation register 2 in response to an instruction of a L/I selection signal provided from the control unit 500. The selected output is, as a burst address operation variable N, consecutively inputted into the burst address generating circuits 100, 200.

The L/I selector 3 selects an output of the linear operation register 1 when the L/I selection signal instructs to generate a linear burst address. The L/I selector 3 selects an output of the interleave operation register 2 when the L/I selection signal instructs to generate an interleave burst address.

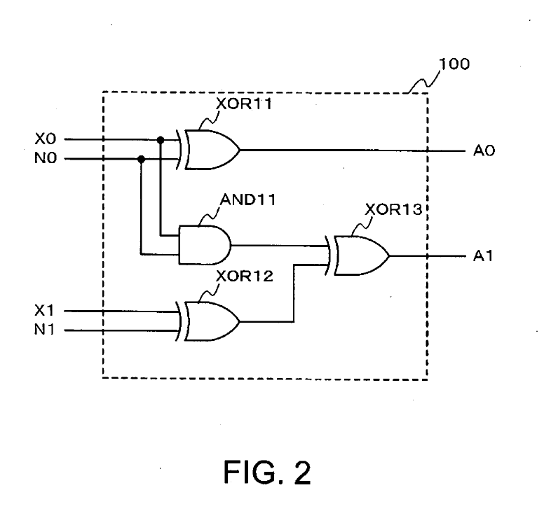

FIG. 2 shows an example of a logical operation circuit in the burst address generating circuit 100. The example is a logical operation circuit for the case that the burst address bit number is “2” and the burst length is “4”.

The burst length indicates the number of address spaces occupied by burst addresses among all of the address spaces of a memory. For example, in the case that the number of all of address bits is “6”, the number of address spaces is “64”. Further, in the case that the number of burst address bits is “2” among the “6”, the number of burst address spaces is “4” and the burst length is “4”.

The logical operation circuit is provided with an exclusive OR gate XOR11, an AND gate AND11, an exclusive OR gate XOR12 and an exclusive OR gate XOR13.

According to the example of FIG. 2, each burst address A shown in FIG. 1 has two bits (four values). For convenience of explanation, the bit values of the burst address A are indicated as A0 and A1 respectively, as shown in FIG. 2. When the burst address A has data “01”, A0 is “0”, and A1 is “1”. Further, in the example, each lap address X shown in FIG. 1 has two bits. The respective bit values are indicated as X0 and X1. When the lap address X has data “01”, X0 is “0” and X1 is “1”. In the example, each burst address operation variable N shown in FIG. 1 has two bits. The respective bit values are indicated as N0 and N1. When the burst address operation variable N has data “01”, NO is “0”, and N1 is “1”.

Input ends of the exclusive OR gate XOR11 are commonly connected to input ends of the AND gate AND 11. The bit values X0, N0 are inputted into the exclusive OR circuit XOR11, and the exclusive OR circuit XOR11 outputs the bit value A0. An output end of the AND gate AND11 is connected to an input end of the exclusive OR circuit XOR13. An output end of the exclusive OR circuit XOR12 is connected to another input of the exclusive OR circuit XOR13. The bit values X1, N1 are inputted into the exclusive OR gate XOR12. The bit values X0, N0 are inputted into the AND gate AND11. The outputs of the AND gate AND11 and the exclusive OR gate XOR12 are connected to the input ends of the exclusive OR gate XOR13. The bit value A1 is outputted from the exclusive OR gate XOR13.

The logical operation performed by the circuit of FIG. 2 is expressed by the following logical formulas. “XOR” indicates exclusive OR, and “AND” indicates logical product.

A0=X0 XOR N0 (1)

A1=X1 XOR N1XOR(X0AND N0) (2)

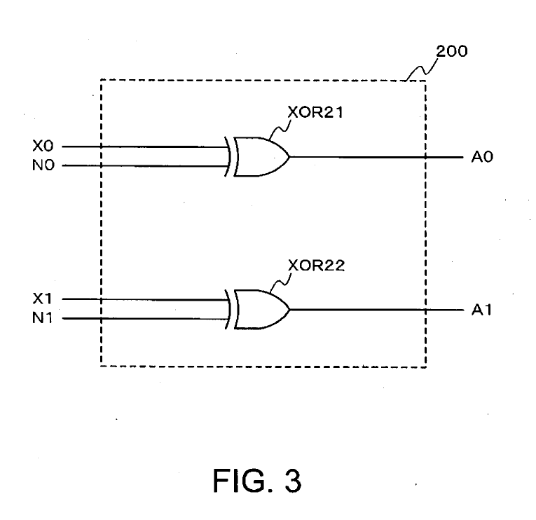

FIG. 3 shows an example of a logical operation circuit in the burst address generating circuit 200. The example is a logical operation circuit for the case that the burst address bit number is “2” and the burst length is “4”. In FIG. 3, A0, A1, X0, X1, N0 and N1 indicate the bit values as stated above. The bit values X0, N0 are inputted into an exclusive OR circuit XOR21 and the bit value A0 is outputted from the exclusive OR circuit XOR21. The bit values X1, N1 are inputted into an exclusive OR circuit XOR22, and the bit value A1 is outputted from the exclusive OR circuit XOR22. The logical operation of the circuit is expressed by the following logical formulas.

A0=X0 XOR N0 (3)

A1=X1 XOR N1 (4)

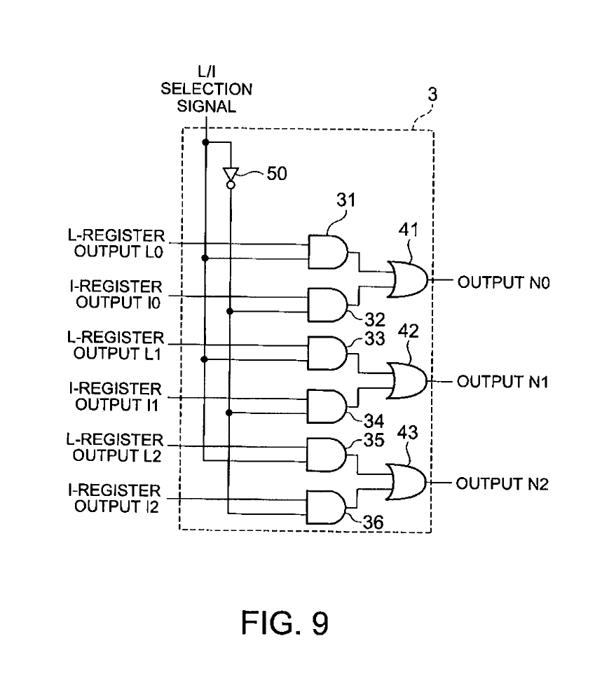

FIG. 9 is a circuit diagram showing an example of the L/I selector 3. The example is a circuit for the case that the burst address bit number is “3” and the burst length is “8”. According to the circuit, the linear operation variable L is selected when the L/I selection signal is at an “H (high)” level, and the interleave operation variable I is selected when the L/I selection signal is at an “L (low)” level.

The L/I selector 3 is provided with AND gates 31-36, OR gates 41-43 and an inverter 50 which are respectively connected with each other as shown in FIG. 9. The L/I selection signal is inputted into the AND gates 31, 33 and 35, and the inverter 50. An output of the inverter 50 is inputted into the AND gates 32, 34 and 36. Outputs L0-L2 of the linear operation register 1 and outputs I0-I2 of the interleave operation register 2 are respectively inputted into the AND gates 31-36. The input terminal of the OR gate 41 is connected to the output terminals of the AND gates 31, 32. The input terminal of the OR gate 42 is connected to the output terminals of the AND gates 33, 34 in the same manner. The input terminal of the OR gate 43 is connected to the output terminals of the AND gates 35, 36. From the OR gates 41-43, outputs N0-N2 of the L/I selector 3 are obtained.

The pattern generator 300 outputs lap address X in response to an address instruction signal provided from the control unit 500. The burst address generating circuit 100 performs the predetermined logical operation described above, based on the lap address X outputted from the pattern generator 300 and the burst address operation variable N outputted from the L/I selector 3. Similarly, the burst address generating circuit 200 performs the predetermined logical operation described above, based on the lap address X and the burst address operation variable N, as will be also described in detail below. The burst address generating circuits 100, 200 output the results AL, AI of the logical operations to the selector 400, respectively.

When the L/I selection signal instructs to generate linear burst address, the selector 400 selects the output of the burst address generating circuit 100, and outputs the generated linear burst address as a burst address A. When the LIT selection signal instructs to generate interleave burst address, the selector 400 selects the output of the burst address generating circuit 200, and outputs the generated interleave burst address as the burst address A.

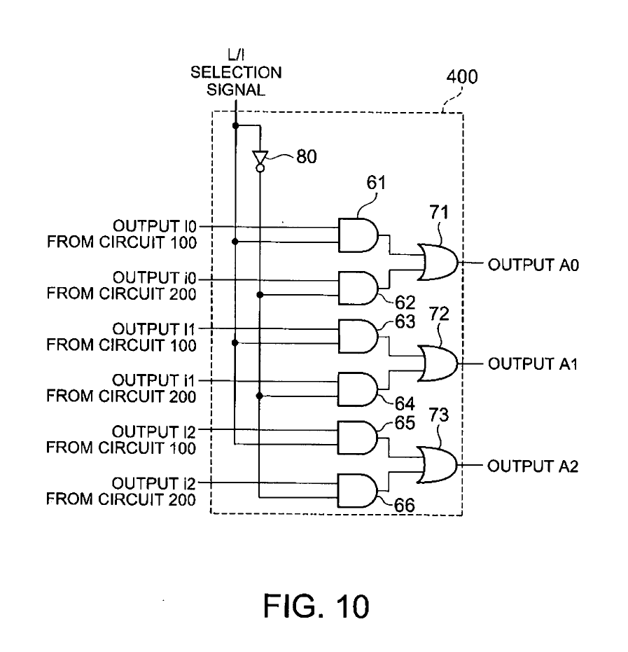

FIG. 10 is a circuit diagram showing an example of the selector 400. The example is a circuit for the case that the burst address bit number is “3” and the burst length is “8”. According to the circuit, the linear operation variable L is selected when the L/I selection signal is at an “H” level, and the interleave operation variable I is selected when the L/I selection signal is at an “L” level.

The selector 400 is provided with AND gates 61-66, OR gates 71-73 and an inverter 80 which are respectively connected as shown in FIG. 10. The L/I selection signal is inputted into the AND gates 61, 63 and 65, and into the inverter 80. An output of the inverter 80 is inputted into the AND gates 62, 64 and 66. Outputs 10-12 of the burst address generating circuit 100 and outputs i0-i2 of the burst address generating circuit 200 are respectively inputted into the AND gates 61-66. The input terminal of the OR gate 71 is connected to the output terminals of the AND gates 61, 62. The input terminal of the OR gate 72 is connected to the output terminals of the AND gates 63, 64 in the same manner. The input terminal of the OR gate 73 is connected to the output terminals of the AND gates 65, 66. From the OR gates 71-73, outputs A0-A2 of the selector 400 are obtained.

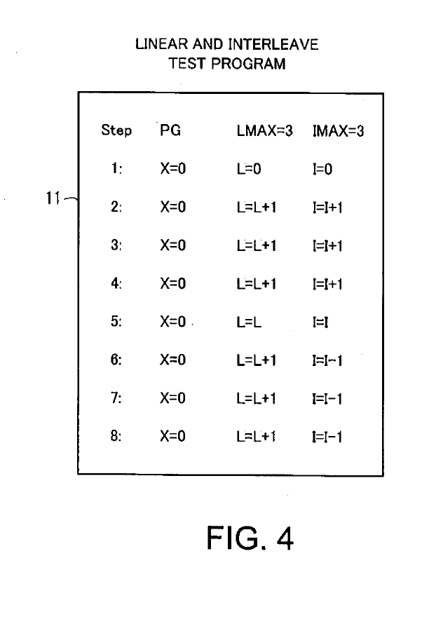

FIG. 4 shows a description example of a test program to be executed in the memory tester according to the embodiment. The description example is an example for the case that the burst length is 4. The description defines the burst lengths by LMAX for linear use and IMAX for interleave. The description example contains steps 1 to 8.

The test program is installed in the control unit 500. In each step line of the test program, an address value X of each lap address and operation formulas to calculate the linear and interleave operation variable L, I are described, in order that each step number and each address value X and each of the operation formulas correspond to each other. Each address value X is described to produce the value X by the pattern generator (PG) 300.

The test program of FIG. 4 is an example of the case that LMAX=3 and IMAX=3. The respective values of the linear operation variable L and the interleave operation variable I are limited to 0, 1, 2 or 3. The respective values are limited to 0 to 3 in the test program. Accordingly, when the operation result reaches “4”, the linear or interleave operation variable L or I obtained as an operation result is replaced with “0”. For example, in Step 6, the value of the linear operation variable L is replaced with L=0, since the operation result of the operation formula L=L+1becomes L=4.

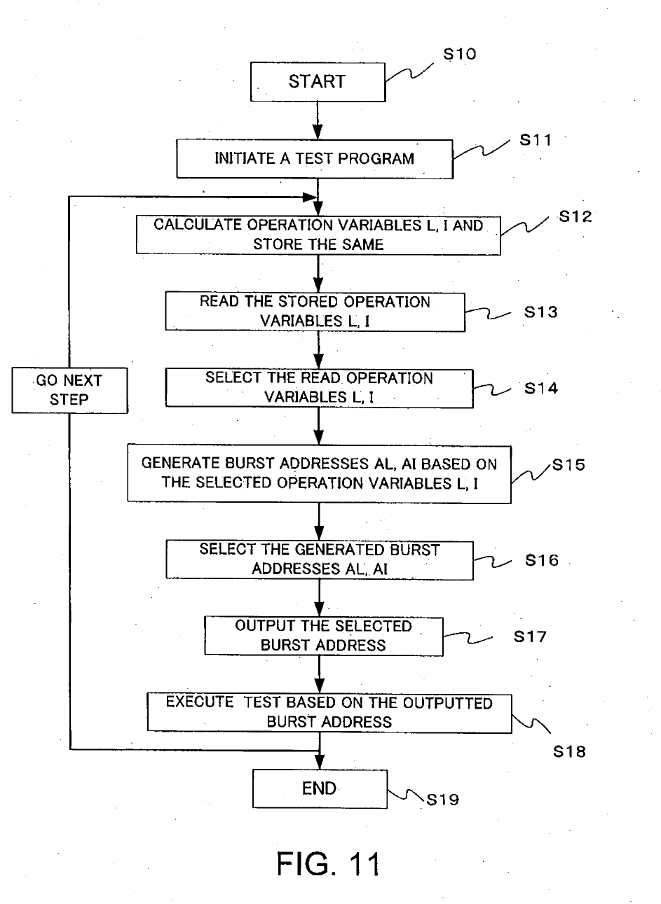

In the control unit 500, object files which are obtained by compiling the test program are installed and executed. FIG. 11 is a flow chart to generate a burst address using the memory tester according to the embodiment. The flow will be described below with reference to FIG. 11.

In FIG. 11, the memory tester shown in FIG. 1 is set up (Step S10). With the set-up of the memory tester, the object files of the test program shown in FIG. 4 are initiated (Step S11). With the initiation of the test program, linear and interleave operation variables L, I are calculated in accordance with the order of the steps 1 to 8 of FIG. 4. In the step 1, linear and interleave operation variables L, I are calculated using an operation formula described in the step 1.

The calculated values of the linear and interleave operation variables L, I are stored in the linear and interleave operation registers 1, 2, respectively, by instruction of the R/W signal provided from the control unit 500 of FIG. 1 (Step S12). The stored values of the linear and interleave operation variables L. I are read from the linear and interleave operation registers 1, 2 respectively by instruction of the R/W signal (Step S13).

Further, when a linear burst address needs to be generated, for example, the L/I selector 3 selects an output from the linear operation register 1 as the burst address operation variable N, in response to the instruction given by an L/I selection signal of FIG. 1 (Step S14). The burst address generating circuits 100, 200 produce a linear burst address AL and an interleave burst address AI, respectively (Step S15). Further, the selector 400 selects an output of the burst address generating circuit 100 as the burst address A (Step S16). The burst address A is outputted from the selector 400 (Step S17), and a test is carried out (Step S18). Further, in the next step 2 of the test program, a linear operation variable L and an interleave operation variable I are calculated. The calculated values are stored in the linear and interleave operation registers 1, 2. Hereafter, the same processing as the above described processing is repeated. After the repeat of processing in accordance with the step 2 to 8, execution of the test is ended (Step S19).

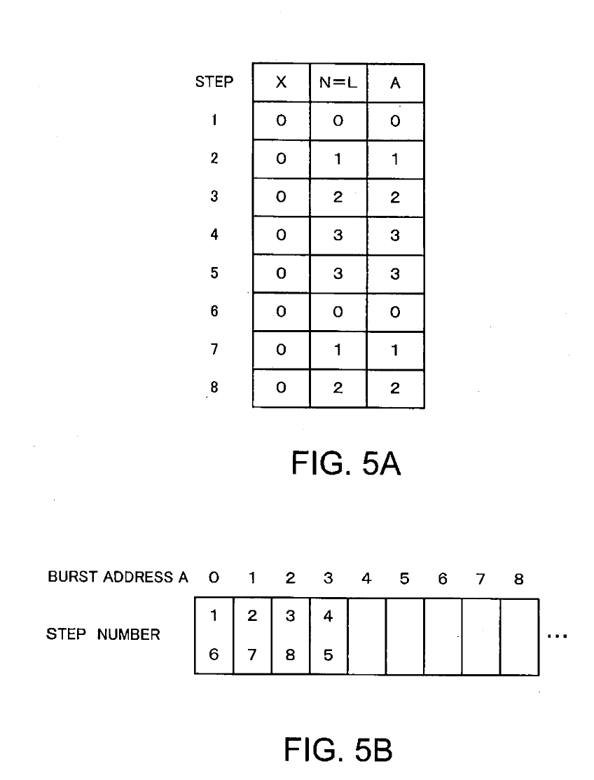

FIGS. 5A and 5B show example values generated in the steps 1 to 8 of the test program of FIG. 4. In this case, the L/I selector 3 selects an output of the linear operation register 1 as the burst address operation variable N, in response to the instruction given by the L/I selection signal of FIG. 1. Further, the selector 400 selects an output of the linear burst address generating circuit 100 as the burst address A.

FIG. 5A shows a relationship of values of the lap address X, values of the burst address operation variable N (=a linear operation variable L), and values of the burst address A (=a linear burst address) outputted from the selector 400, which are generated in each of the steps 1 to 8 shown in FIG. 4.

FIG. 5B shows a generating order of values of the burst address A. The values of the burst address A are generated according to the respective step 1 to 8 of FIG. 4. In this case, the values of the burst address A (=a linear burst address) are generated in the order of 0→1→2→3→3→0→1→2.

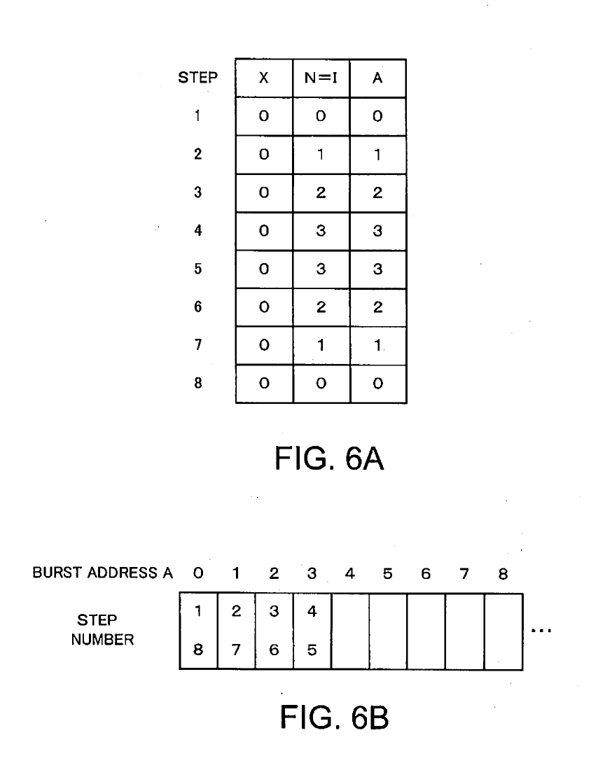

FIGS. 6A and 6B show example values generated in the steps 1 to 8 of the test program of FIG. 4. In this case, the L/I selector 3 selects an output of the interleave operation register 2 as the burst address operation variable N, in response to the instruction given by the L/I selection signal of FIG. 1. Further, the selector 400 selects an output of the interleave burst address generating circuit 200 as the burst address A.

FIG. 6A shows a relationship of values of the lap address X, values of the burst address operation variable N (=an interleave operation variable I), and values of the burst address A (=an interleave burst address) outputted from the selector 400, in respective steps of FIG. 4.

FIG. 5B shows the generating order of values of the burst address A. In this case, the burst address A (=an interleave burst address) are generated in the order of 0→1→2→3→3→2→1→0.

According to the embodiment, the test program is commonly executed for linear and interleave, so that each linear operation variable L and each interleave operation variable I obtained as a result of executing the test program is separately stored in each of the linear and interleave operation registers 1, 2. Further, the output of either one of the registers 1, 2 can be selected in response to the instruction given by the L/I selection signal, and is inputted into the burst address generating circuits 100 and 200 as a burst address operation variable N. Thus, the linear or interleave burst address can be generated without preparing separate test programs for linear and interleave uses. Accordingly, the efficiency of creating a test program can be enhanced.

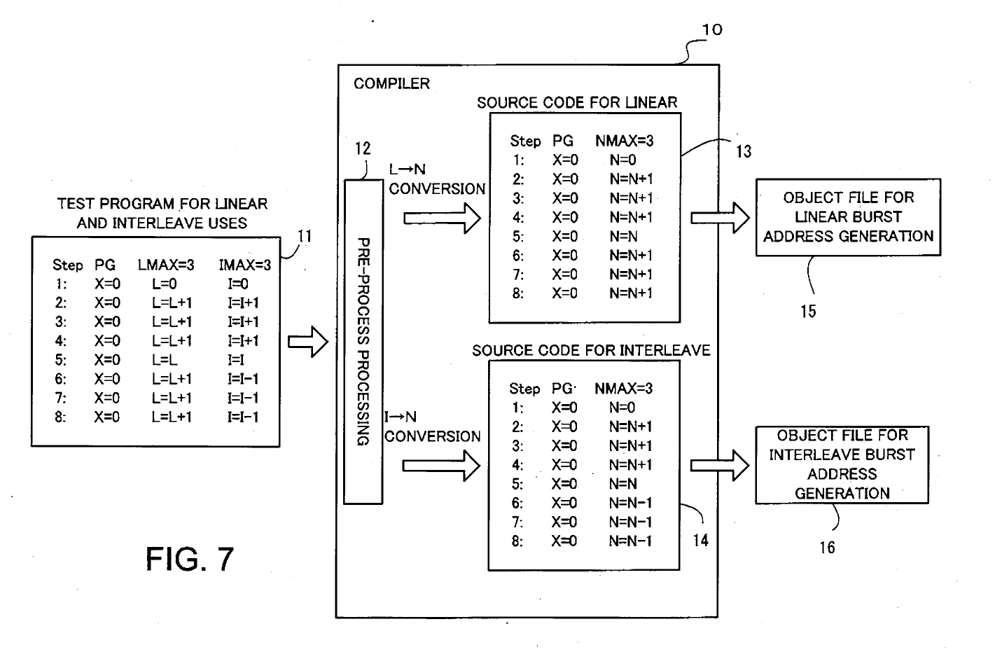

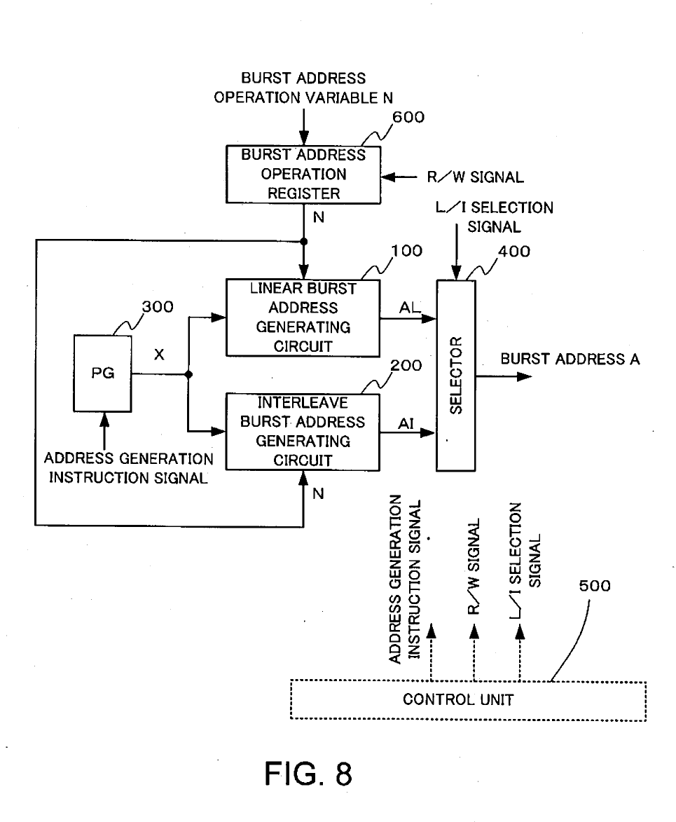

FIG. 8 is a block diagram showing an example of a memory tester in which object files for linear and interleave uses are executed alternatively. The object files for linear and interleave uses, which will be described in detail below, are produced by execution of an example of a compiler 10 shown in FIG. 7.

The memory tester of FIG. 8 is provided with units similar to those of the memory tester shown in FIG. 1, with the exception that units corresponding to the linear and interleave operation register 1, 2 and the L/I selector 3 do not exist but that a burst address operation register 600 is provided instead.

The burst address operation register 600 stores a burst address operation variable N obtained by execution of the object file for linear or interleave use. The stored variable N is read from the burst address operation register 600, and is inputted to burst address generating circuits 100, 200. The compiler 10 shown in FIG. 7 is software for generating two separate object files based on two source codes. The source codes are produced from one unit of test program 11 shown in FIG. 4. The compiler 10 is installed in a computer (not shown) and is executed by the computer. The computer, in which the compiler 10 is installed, functions as a compiler apparatus. The test program 1 is capable of being used commonly to generate linear and interleave burst addresses AL, AI.

The compiler 10 is used to produce two source codes 13, 14 for linear and interleave uses based on the data described in the test program 11. The produced source codes 13, 14 are stored in the computer, and the stored source codes are converted into object files 15, 16, respectively by execution of the compiler 10. The obtained object files are stored in the computer. The compiler 10 includes pre-process processing 12 for the test program 11, which will be described below.

Use of such a compiler does not necessitate linear and interleave operation register and an L/I selector as employed in the above embodiment.

The source code 13 includes logical formulas for calculating a burst address operation variable N for linear use, which correspond to respective steps of calculating the linear operation variable L described in the test program 11. The source code includes logical formulas for calculating a burst address operation variable N for interleave, which correspond to respective steps of calculating the interleave operation variable I described in the test program 11. The source codes 13, 14 are separately produced. The object files 15, 16 are generated from the source codes 13, 14 by execution of the compiler. One of the object files 15, 16 is used to generate a linear burst address. The other of the object files 15, 16 is used to generate an interleave burst address.

The pre-process processing 12 is performed before the compiler 10 is executed to produce the object codes. The descriptions of the linear operation variable L are respectively converted into those of the burst address operation variable N through the pre-process processing. This processing will be simply mentioned as “L→N conversion”, hereinafter. Further, the descriptions of the interleave operation variable I are respectively converted into those of the burst address operation variable N through the pre-process processing. This processing will be simply mentioned as “I→N conversion”, hereinafter.

The pre-process processing produces both a source code 13 including logical formulas for calculating a burst address operation variable N for linear use and a source code 14 including logical formulas for calculating a burst address operation variable N for interleave.

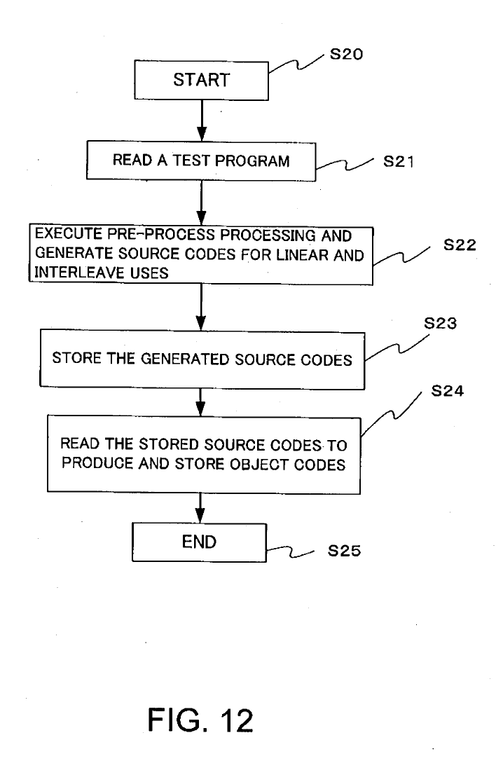

FIG. 12 is a flow chart to produce the object files15, 16 for generating two kinds of burst addresses by the compiling described above. The compiler 10 is installed in a computer (not shown), and the test program 11 for both linear and interleave uses is also stored in the computer.

In FIG. 12, the compiler 10 is initiated (Step S20). The test program 11 stored in the computer is read (Step S21).

By a pre-process processing 12, an L→N conversion and an I→N conversion are performed. Source codes 13, 14 for linear and interleave uses are respectively produced by the pre-process processing (Step S22). The linear operation variable L is described as the burst address operation variable N in the source code 13. The interleave operation variable I are described as the burst address operation variable N in the source code 14. The produced source codes 13, 14 are stored in the computer (Step S23).

Subsequently, the stored source code 13, 14 are read and compiled by execution of the compiler 10 respectively, and the object file 15 for generating a linear burst address and the object file 16 for generating an interleave burst address are generated and stored in the computer (Step S24). By finishing storing the data of the object files 15, 16, the compiling is completed (Step S25).

The object files 15, 16 are selected alternatively by an operator, and are stored in the control unit 500 of the memory tester of FIG. 8. Further, the L/I selection signal is produced by the control unit 500 corresponding to the selection of the object files 15, 16.

The object file 15 or 16 stored in the control unit 500 is executed so as to produce a burst address operation variable N and so as to input the same into the burst address operation register 600. Further, the burst address generating circuit 100, 200 are operated. As a result, either linear or interleave burst address A is outputted from the selector 400 that operates in response to the L/I selection signal.

The linear and interleave object files are generated by execution of the compiler 10 based on the one unit of test program 11 where the linear and interleave operation variables L, I are described. The generated object files are selectively stored in the control unit 500 of the memory tester. The stored one of the object files are executed to generate the linear or interleave burst address.

In the case that the compiler 10 of FIG. 7 and the memory tester of FIG. 8 are employed as described above, one unit of test program is sufficient for generating the linear and the interleave burst addresses, and a plurality of separate test programs is not required to be prepared. This enhances the efficiency for creating test program.

In the embodiment of FIG. 1, the L/I selection signal is provided from the control unit 500. The L/I selection signal may be provided from another unit other than the control unit 500, instead. In addition, the selector 400 shown in FIG. 400 may be omitted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory tester comprising:
a first operation register to store a first operation variable;
a second operation register to store a second operation variable;
a first selector to output the first or second operation variables stored in the first and second operation registers, selectively, as a burst address operation variable, based on a selection signal,
a first burst address generating circuit capable of generating a first burst address signal based on the first operation variable outputted from the first selector; and .
a second burst address generating circuit capable of generating a second burst address signal based on the second operation variable outputted from the first selector.

2. The memory tester according to claim 1, wherein the first operation variable is for a linear use, the second operation variable is for an interleave use, the first burst address is for the linear use, and the second burst address is for the interleave use.

3. The memory tester according to claim 2, further comprising a pattern generator to generate a lap address, wherein the lap address is provided from the pattern generator to the first and second burst address generating circuits.

4. The memory tester according to claim 3, further comprising a second selector, wherein the second selector selects and outputs the first or second burst address signal from the first or second burst address generating circuit, based on the selection signal.

5. The memory tester according to claim 4, further comprising a control unit configured to generate the selection signal.

6. The memory tester according to claim 5, wherein the control unit generates R/W signal and outputs the R/W signal into the first operation register and the second operation register to control the first operation register and the second operation register.

7. The memory tester according to claim 4, wherein the first and second operation variables are obtained by executing one unit of test program containing logical formulas for obtaining the operation variables.

8. The memory tester according to claim 5, further comprising a control unit, wherein the test program can be installed in the control unit, the control unit can provide an address generating instruction signal to the pattern generator, and the control unit can further provide write and read signals to the first and second operation resisters.

9. A compiler which is capable of being executed by a computer, comprising:
converting first and second operation variables described in one unit of test program into first and second burst address operation variables, respectively;
generating a first source code including the obtained first burst address operation variable and generating a second source code including the obtained second burst address operation variable, the first source code being separated from the second source code; and
compiling the first and second source codes and generating first and second object files, respectively.

10. The compiler according to claim 9, wherein the first operation variable is for a linear use, the second operation variable is for an interleave use, the first burst address is for the linear use, and the second burst address is for the interleave use.
